(19) United States
(12) Patent Application Publication
(10) Pub. No.: US 2009/0230378 A1
(43) Pub. Date: Sep. 17, 2009

(54) RESISTIVE MEMORY DEVICES

(75) Inventors: Kyung-Chang Ryoo, Gyeonggi-do (KR); Hong-Sik Jeong, Gyeonggi-do (KR); Gi-Tae Jeong, Seoul (KR); Hyeong-Jun Kim, Seoul (KR); Dong-Won Lim, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/273,271

(22) Filed: Nov. 18, 2008

(30) Foreign Application Priority Data
Mar. 11, 2008 (KR) 10-2008-0022448

(51) Int. Cl. H01L 45/00

(52) U.S. Cl. 257/4; 257/E45.002

(57) ABSTRACT

Provided is a resistive memory device that can be integrated with a high integration density and method of forming the same. An insulating layer enclosing a resistive memory element and an insulating layer enclosing a conductive line connected with the resistive memory element have different stresses, hardness, porosity degrees, dielectric constant or heat conductivities.

### CROSS-REFERENCE TO RELATED APPLICATIONS

This U.S. non-provisional patent application claims priority under 35 U.S.C. §119 of Korean Patent Application No. 10-2008-0022448, filed on Mar. 11, 2008, the entire contents of which are hereby incorporated by reference.

### BACKGROUND

Embodiments of the present invention relate to resistive memory devices and methods of forming the same, and more particularly, to phase-change memory devices that can be integrated with a high integration density and methods of forming the same.

Phase-change memory devices are memory devices to store and read information using a difference in electrical conductivity (or resistivity) of phase-change material, for example, chalcogenide. These phase-change memory devices are highlighted as a next generation memory owing to their characteristics, such as random access and nonvolatility.

However, like other memory devices, since the phase-change memory devices require a higher level of integration density, a new phase-change memory device capable of satisfying such a requirement and a method of forming the same are needed.

### SUMMARY

Embodiments of the present invention provide resistive memory devices with a high integration density and method of forming the same.

Embodiments of the present invention also provide phase-change memory devices with a high integration density and method of forming the same.

In some embodiments of the present invention, resistive memory devices include a resistive memory element formed on a substrate. A first insulating layer covers a side surface of the resistive memory element. A conductive line is provided on the resistive memory element. A second insulating layer covers a side surface of the conductive line. The first insulating layer and the second insulating layer have a difference in at least one selected from the group consisting of hardness, stress, dielectric constant, heat conductivity and porosity degree.

In other embodiments of the present invention, methods of forming a resistive memory device comprise forming a first insulating layer having a first opening on a substrate. A resistive memory element is formed in the first opening. A second insulating layer having an opening exposing the resistive memory element is formed on the resistive memory element and the first insulating layer. A conductive line connected with the resistive memory element is formed by filling the opening with a conducive material. The first insulating layer and the second insulating layer are formed such that the first insulating layer and the second insulating layer have at least one difference in characters, characters such as hardness, stress, dielectric constant, heat conductivity and porosity degree.

In still other embodiments of the present invention, methods of forming a resistive memory device comprise forming a resistive memory element on a substrate. A first insulating layer covering a sidewall of the resistive memory element is formed on the substrate. A second insulating layer having an opening exposing the resistive memory element is formed on the resistive memory element and the first insulating layer. A conductive line connected with the resistive memory element is formed by filling the opening with a conductive material. The first insulating layer and the second insulating layer are formed such that the first insulating layer and the second insulating layer have at least one difference in characters, characters such as hardness, stress, dielectric constant, heat conductivity and porosity degree.

### BRIEF DESCRIPTION OF THE DRAWINGS

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a plan view illustrating some of a cell array region of a substrate on which a resistive memory device is formed according to an embodiment of the present invention;

FIG. 2 is an equivalent circuit diagram of some of a cell array region of a resistive memory device according to an embodiment of the present invention;

FIGS. 3 through 7 are sectional views for explaining a method of forming a phase-change memory device according to an embodiment of the present invention;

FIGS. 8 and 9 are plan views illustrating various patterns of phase-change materials according to embodiments of the present invention;

FIGS. 10 through 13 are partial sectional views for explaining a method of forming the phase-change memory device of FIG. 3;

FIG. 14 illustrates a phase-change memory device according to an embodiment of the present invention;

FIGS. 15 through 18 are partial sectional views for explaining a method of forming the phase-change memory device of FIG. 4;

FIGS. 19 through 22 are partial sectional views for explaining a method of forming the phase-change memory device of FIG. 5;

FIGS. 23 through 26 are partial sectional views for explaining a method of forming the phase-change memory device of FIG. 6;

FIGS. 27 through 29 are partial sectional views for explaining a method of forming the phase-change memory device of FIG. 7;

FIG. 30 is sectional views illustrating a phase-change memory device according to an embodiment of the present invention; and

FIGS. 31 through 38 show apparatuses including a resistive memory device according to embodiments of the present invention.

### DETAILED DESCRIPTION OF EMBODIMENTS

Embodiments of the present invention relate to resistive memory devices and methods of forming the same. A resistive memory device is a type of memory device using a resistive memory element that can represent at least two resistive states discernible according to a signal applied, e.g., high resistive state and low resistive state. The resistive memory element may include, for example, a perovskite memory element, a phase-change memory element, a magneto-resistive memory element, a conductive metal oxide (CMO) memory element, a solid electrolyte memory element, a polymer memory element and the like.

The perovskite memory element may include, for example, a colossal magnetoresistive (CMR) material, a high temperature superconducting (HTSC) material, or the like. The solid electrolyte memory element has metal ions movable in a solid electrolyte, and thus the solid electrolyte memory element may include a material that can form a conductive bridging.

Example embodiments of the present invention will now be described using a resistive memory device employing a phase-change memory element. Accordingly, it will be understood that descriptions to be mentioned below may be applied to resistive memory devices employing various types of memory elements described above.

An embodiment of the present invention provides a phase-change memory device and a method of forming the same. The phase-change memory device according to an embodiment of the present invention includes a phase-change memory element. The phase-change memory element may include a phase-change material. For example, it will be understood that the phase-change memory element may indicate a phase-change material layer and two electrodes connected with both surfaces of the phase-change material layer. Also, it will be understood that the phase-change memory element indicates a phase-change material. The phase-change material may be a material of which crystalline state may be reversely changed between a plurality of crystalline states showing different resistive states depending on heat. Electrical signals, such as current, voltage, optical signals, radiation or the like may be used to change the crystalline state of the phase-change material. For example, when a current flows between electrodes connected with both ends of a phase-change material, heat is provided to the phase-change material by a resistive heating. At this time, the crystalline state of the phase-change material may be changed depending on intensity of heat provided and time provided. For example, the phase-change material may have an amorphous state (or reset state) with a high resistance and a crystalline state (or set state) with a low resistance.

The phase-change material may include, for example, chalcogenide. When a phase-change material according to embodiments of the present invention is expressed by ‘XY’, ‘X’ may include at least one selected from the group consisting of telulium (Te), Selenium (Se), Sulphur (S), and polonium (Po), and ‘Y’ may include at least one selected from the group consisting of Antimony (Sb), Arsenic (As), Germanium (Ge), Tin (Sn), Phosphorous (P), Oxygen (O), Indium (In), Bismuth (Bi), Silver (Ag), Gold (Au), Palladium (Pd), Titanium (Ti), Boron (B), Nitrogen (N) and Silicon (Si). Examples of the phase-change material according to an embodiment of the present invention may include chalcogenides such as Ge—Sb—Te (GST), Ge—Bi—Te (GBT), As—Sb—Te, As—Ge—Sb—Te, Sn—Sb—Te, In—Sn—Sb—Te, Ag—In—Sb—Te, an element in Group 5A of the periodic table-Sb—Te, an element in Group 6A of the periodic table-Sb—Te, an element in Group 5A of the periodic table-Sb—Se, an element in Group 6A of the periodic table-Sb—Se, and chalcogenides in which impurities are doped in the aforementioned chalcogenides. The impurities doped in the chalcogenides may include, for example, nitrogen, oxygen, silicon, or combinations thereof.

Embodiments of the present invention provide methods of forming an insulating layer for insulation between phase-change memory elements, and an insulating layer for insulation between conductive structures, for example, conductive lines. Also, an embodiment of the present invention provides a method of forming a variety of conductive lines such as a bit line and a word line in a cell array region, and a local conductive line in a peripheral circuit region, as well as an interconnecting method between conductive structures in a phase-change memory device.

As the degree of integration increases, a distance between elements in a horizontal direction, a distance between a variety of conductive lines such as a bit line and a local conductive line, and a line width of such conductive lines decreases, but a height of insulating layers and conductive layers stacked on a substrate in a vertical direction increases. For example, in the case of a phase-change memory element, its height and width decrease. The distance between adjacent phase-change memory elements decreases too.

When a phase-change memory element is formed under this circumstance, the inventors of the present invention have found that the phase-change memory element is distorted due to a thermal process, etc. Also, the inventors have found that if the phase-change memory element, in particular, the phase-change material is distorted, an interfacial characteristic between the phase-change material and electrodes is deteriorated and thus a set resistance increases.

According to embodiments of the present invention, in order to prevent a phase-change memory element and a phase-change material layer from being distorted, a phase-change material layer and an insulating layer enclosing a phase-change material layer have the same stress property. For example, an insulating layer enclosing a phase-change memory element shows ‘tensile stress’. The insulating layer enclosing the phase-change memory element may be formed of a material having a stress property that can compensate for a stress that a phase-change memory element has in a memory operation. The insulating layer enclosing the phase-change memory element may have, for example, a tensile stress of about 5×10⁹ dyne/cm².

According to other embodiments of the present invention, an insulating layer enclosing a phase-change memory element may be formed of a material with a high hardness to minimize the movement of the phase-change memory element.

Also, according to still other embodiments of the present invention, an insulating layer enclosing a phase-change memory element may be formed of a material with low heat conductivity. Thus, it is possible to reduce a thermal interference between adjacent phase-change memory elements.

The height increase in the vertical direction may cause an increase in the aspect ratio in various openings, such as a contact hole, a via-hole, etc., for an electrical connection between lower and upper conductive structures and conductive lines, between conductive structures, or between conductive lines. As the distance between adjacent conductive lines decreases, it becomes difficult to form a conductive line using an etching, and the resistance of a conductive line increases due to a decrease in the line width. Also, as the aspect ratio of opening increases, it becomes difficult to fill an opening with a conductive material, and the resistance of a conductive material filled in an opening also increases.

Accordingly, in an embodiment of the present invention, at least one conductive line, for example, a bit line is formed of copper using a damascene technique. To decrease the parasitic capacitance between adjacent conductive lines, an insulating layer enclosing a conductive line may be formed of, for example, a low-k material with low dielectric constant. For example, an insulating layer covering side surfaces of a conductive line, such as a bit line may be formed of a material having a dielectric constant lower than the insulating layer formed on side surfaces of the phase-change memory element.

In other embodiments of the present invention, an insulating layer enclosing a conductive line may be formed of a porous material in order to obtain a low dielectric constant. For example, an insulating layer enclosing a conductive line may be formed of a material having a higher porosity degree than an insulating layer enclosing a phase-change memory element. In still other embodiments of the present invention, an insulating layer enclosing a conductive line may be formed of a material having a lower hardness than an insulating layer enclosing a phase-change memory element.

In even other embodiments of the present invention, an insulating layer enclosing a conductive line may be formed of a material having a lower tensile stress than an insulating layer enclosing a phase-change memory element.

According to another embodiment of the present invention, when a copper bit line is formed using a damascene technique, a part of a contact structure for an electrical connection between conductive regions, between a conductive region and a conductive line, or between conductive lines is formed of copper at a position adjacent to the copper bit line. For example, when a stripe type opening for a bit line is formed, a hole type opening for a part of a contact structure is formed, the stripe type opening for a bit line is filled with copper to form a copper bit line, and the opening for a part of a contact structure is filled with copper to form a copper stud.

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, like reference numerals in the drawings denote like elements, and thus their description will be omitted.

Terms such as “lower surface” and “upper surface” used in relation to elements of the present specification are relative terms which indicate a “relatively close surface to” and a “relatively distant surface from” a main surface of a substrate, respectively. Also, it will be understood that in the present specification, the heights of elements' surfaces may be compared with respect to a main surface of a substrate. For example, it will be understood that when a lower surface of one element is referred to as being “lower” than a lower surface of another element, the description may indicate that the lower surface of the one element is positioned closer to a main surface of a substrate than the lower surface of the other element.

A term ‘conductive material’ used in the present specification includes, but is not limited to, metal, conductive metal nitride, conductive metal oxide, conductive oxide nitride, silicide, metal alloy or combinations thereof. Examples of the metal include copper (Cu), aluminum (Al), tungsten titanium (TiW), tantalum (Ta), Molybdenum (Mo), tungsten (W) and the like. Conductive metal nitride includes, but is not limited to, for example, titanium nitride (TiN), tantalum nitride (TaN), Molybdenum nitride (MoN), niobium nitride (NbN), titanium silicon nitride (TiSiN), titanium aluminum nitride (TiAlN), titanium boron nitride (TiBN), zirconium silicon nitride (ZrSiN), tungsten silicon nitride (WSiN), tungsten boron nitride (WBN), zirconium aluminum nitride (ZrAlN), molybdenum silicon nitride (MoSiN), molybdenum aluminum nitride (MoAlN), tantalum silicon nitride (TaSiN), tantalum aluminum nitride (TaAlN) and the like. Examples of the conductive oxide nitride include, but are not limited to, titanium oxide nitride (TiON), titanium aluminum oxide nitride (TiAlON), tungsten oxide nitride (WON), tantalum oxide nitride (TaON) and the like. Examples of the conductive metal oxide include, but are not limited to, conductive novel metal oxides, such as iridium oxide (IrO), ruthenium oxide (RuO) and the like.

In the present specification, ‘substrate’ or ‘semiconductor substrate’ or ‘semiconductor layer’ may indicate a semiconductor-based structure with a silicon surface. Also, ‘substrate’ or ‘semiconductor substrate’ or ‘semiconductor layer’ may indicate a conductive region, an insulating region, and/or a semiconductor-based structure on which a device is formed. Such a semiconductor based structure may indicate, for example, a silicon layer, a silicon on insulator (SOI) layer, a silicon-germanium (SiGe) layer, a germanium (Ge) layer, a gallium-arsenide (GaAs) layer, a doped or undoped silicon layer, a silicon epitaxial layer supported by a semiconductor structure, or any semiconductor structures.

It will be understood that when an element or layer is referred to as being “on”, or “formed on” another element or layer, it may be directly on or formed on the other element or layer, or intervening elements or layers may be present or formed. Also, it will be understood that, although the terms first, second, third, etc. may be used herein to describe various elements, such as studs, conductive lines, contact plugs, insulating layers, conductive materials, contact holes, via holes, opening and the like throughout the present specification, these elements should not be limited by these terms. These terms may be only used to distinguish one element from another region.

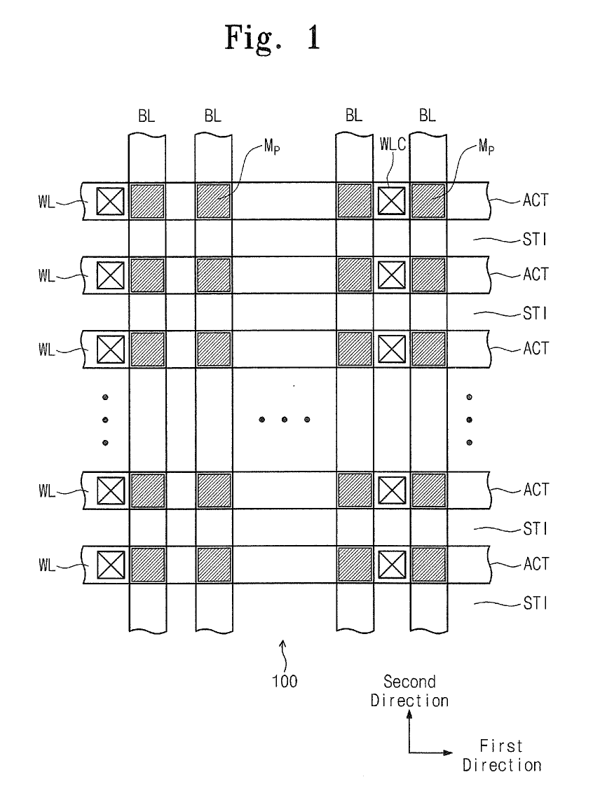

FIG. 1 is a plan view illustrating a part of a cell array region of a substrate 100 provided with a resistive memory device according to an embodiment of the present invention. Referring to FIG. 1, the substrate 100 includes an element region ACT of a stripe pattern extending in a first direction, for example, a row direction. By implanting impurities into this element region ACT, word lines WL may be formed. A shallow trench isolation region STI is positioned at a region other than the element region ACT.

Bit lines BL of a stripe pattern extending in a column direction are arranged to cross the word lines WL. Memory cells may be positioned at crossing portions of the bit lines BL and the word lines WL. In an embodiment of the present invention, a memory cell may include, for example, a resistive memory element Mp, such as a phase-change memory element. One end of the resistive memory element Mp is connected with the bit line BL and the other end is connected with the word line WL. A selection element for selecting the resistive memory element Mp may be positioned between the word line WL and the other end of the resistive memory element Mp. According to an embodiment of the present invention, the resistive memory element Mp may include a phase-change material.

To decrease the resistance of the word line WL, the word line WL may be electrically connected with a conductive line having a low resistance through the word line contact structure WLC. For example, a conductive line with a low resistance used for decreasing the resistance of the word line WL may be referred to as the upper word line UWL in consideration that the conductive line is more distant from the substrate 100 than the word line WL. The word line WL may be referred to as a lower word line in consideration of this upper word line. Also, it will be understood that the word line WL may indicate the upper word line UWL as well as the lower word line LWL. The word line contact structure WLC may be positioned between the resistive memory elements Mp adjacent to each other in the first direction. The word line contact structure WLC may be formed per a predetermined number of memory cell(s), for example, per eight adjacent memory cells. That is, eight memory cells may be arranged between the contact structures WLC adjacent to each other in the first direction. Also, the contact structure WLC may be formed per an unspecified number of memory cells. That is, various numbers of memory cells, for example, sixteen, thirty two memory cells may be arranged between the contact structures WLC adjacent to each other in the first direction.

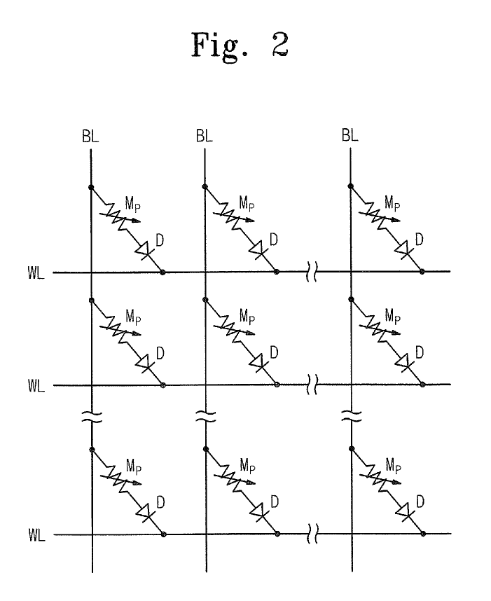

FIG. 2 is an equivalent circuit diagram of a part of a cell array region of a resistive memory device according to an embodiment of the present invention. Referring to FIG. 2, one end of a resistive memory element Mp may be connected with a bit line BL, and the other end may be connected with a word line WL. A selection element D for selecting the memory element Mp may include, but is not limited to, a diode, a MOS transistor, and a MOS diode. A diode D is illustrated as one example of the selection element in FIG. 2.

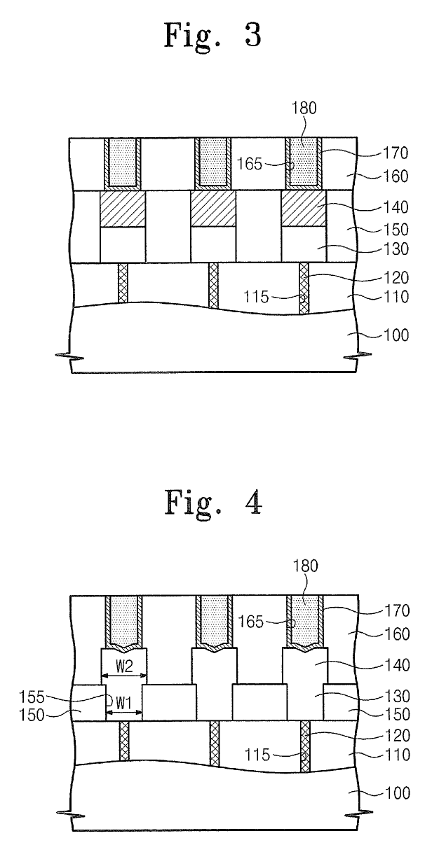

With reference to FIG. 3, a phase-change memory device according to an embodiment of the present invention will now be described. In embodiments to be described below, for convenience of description, an insulating layer enclosing a phase-change memory element, for example, a phase-change material layer is referred to as ‘first insulating layer’ (or cell insulating layer) and an insulating layer enclosing a conductive line, for example, a bit line is referred to as ‘second insulating layer’ (or insulating layer for conductive line).

Referring to FIG. 3, the phase-change material layer 130 connected with the first electrode 120 and the second electrode 140 is provided over the substrate 100. The phase-change material layer 130 may include a chalcogenide. The first electrode 120 is provided between the phase-change material layer 130 and the substrate 100. The first electrode 120 may be defined in the contact hole 115 penetrating the interlayer insulating layer 110 formed on the substrate 100. A conductive line, for example, the bit line 180 is provided on the second electrode 140. That is, the second electrode is provided between the bit line 180 and the phase-change material layer 130. The first insulating layer 150 encloses the phase-change material layer 130. For example, the first insulating layer 150 is provided on a side surface of the phase-change material layer 130. An upper surface of the first insulating layer 150 may be coplanar with an upper surface of the second electrode 140. Accordingly, an upper surface of the phase-change material layer 130 may be lower than the upper surface of the first insulating layer 150.

The second insulating layer 160 encloses the bit line 180. For example, the second insulating layer 160 is provided on a side surface of the bit line 180. The bit line 180 may be defined within the opening 165 of the second insulating layer 160. For example, the bit line 180 may be formed by patterning the second insulating layer 160 to form the opening 165 and then filling a conductive material such as copper in the opening 165. That is, the bit line 180 may be formed by using a damascene technique. The conductive barrier layer 170 may be provided between the copper bit line 180 and the second electrode 140. This conductive barrier layer 170 may be provided on a bottom and sidewalls of the opening 165.

According to the present embodiment, the first insulating layer 150 and the second insulating layer 160 are formed of materials having different properties. The first insulating layer 150 and the second insulating layer 160 show differences in hardness, porosity degree, dielectric constant, stress, and/or heat conductivity. For example, the first insulating layer 150 may be formed of a material with a high hardness, low porosity degree, tensile stress, and/or low heat conductivity. The second insulating layer 160 may be formed of a material with a low hardness, low dielectric constant, and/or a high porosity degree. For example, the first insulating layer 150 may be formed of a material having a relatively higher hardness, higher dielectric constant, lower porosity degree, higher tensile stress, and/or lower heat conductivity than the second insulating layer 160.

For example, the first insulating layer 150 may show a tensile stress of about 5×10⁹ dyne/cm². The second insulating layer 160 may show a lower tensile stress or may not show a tensile stress.

Although not shown in the drawing, a capping layer may be further provided. For example, this capping layer may be formed of silicon oxide (SiO₂), silicon nitride (SiNₓ), silicon oxide nitride (SiON), aluminum oxide (AlOₓ), titanium oxide (TiO₂), or the like. This capping layer may be, for example, provided on the second electrode 140.

FIGS. 4 through 7 are sectional views illustrating phase-change memory devices according to various embodiments of the present invention. When comparing the present embodiments with the embodiment of FIG. 3, the present embodiments are similar to the embodiment of FIG. 3 in that the first insulating layer enclosing the phase-change material layer and the second insulating layer enclosing the bit line are formed of material with different properties, but have some differences in the phase-change material, second electrode, bit line structure and the like than the embodiment described with reference to FIG. 3. These differences will now be described with reference to the accompanying drawings.

Referring to FIG. 4, the phase-change material layer 130 is provided in a contact hole 155 formed in the first insulating layer 150 and on the first insulating layer 150 outside the contact hole 155. For example, the phase-change material layer may be formed by using a damascene technique. The width w2 of the phase-change material layer extending on the first insulating layer 150 may be wider than the width w1 of the phase-change material layer in the contact hole 155. An upper surface of the phase-change material layer 130 is higher than an upper surface of the first insulating layer 150. The first insulating layer 150 covers a part of side surfaces of the phase-change material layer 130, i.e., a lower portion of side surfaces of the phase-change material layer 130. The second insulating layer 160 covers side surfaces of the bit line 180 and a part of side surfaces of the phase-change material layer 130, i.e., an upper portion of side surfaces of the phase-change material layer 130.

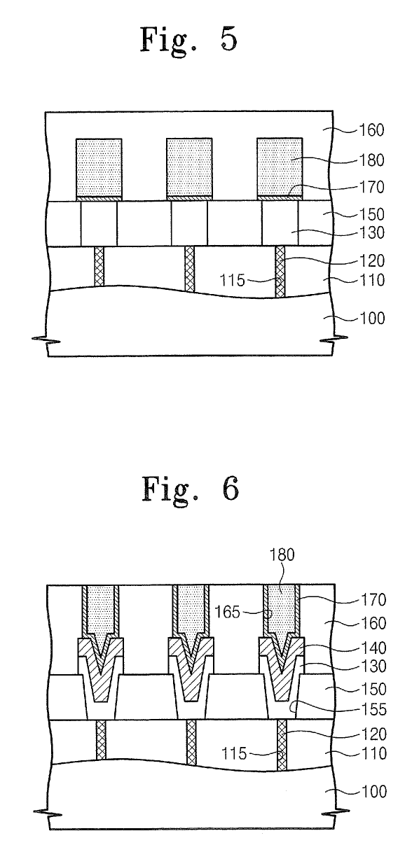

Referring to FIG. 5, unlike the embodiment illustrated in FIG. 4, the phase-change material layer 130 is defined only within the contact hole 155 of the first insulating layer 150. For example, the phase-change material layer 130 may be formed by using a damascene technique. An upper surface of the phase-change material 130 is substantially coplanar with an upper surface of the first insulating layer 150. In the present embodiment, the bit line 180 is provided to contact the phase-change material layer 130. The bit line 180 may be formed by depositing a conductive material on the phase-change material layer 130 and the first insulating layer 150 and then performing a photolithography process that etches the deposited conductive material layer in a predetermined stripe pattern. The second insulating layer 160 is provided on the first insulating layer 150 so that the second insulating layer 160 may cover the bit line 180. In a phase-change memory device according to the present embodiment, a component corresponding to the second electrode 140 of the embodiment illustrated in FIG. 3 is omitted, and the bit line 180 directly contacts the phase-change material layer 130 to function as a second electrode.

Referring to FIG. 6, unlike the embodiment illustrated in FIG. 4, in a phase-change memory device according to the present embodiment, the phase-change material layer 130 may be formed at a constant thickness on a bottom and sidewalls of the contact hole 155. For example, the phase-change material layer 130 fills a part of the contact hole 155 of the first insulating layer 150. A part of the phase-change material layer 130 may extend outward from the contact hole 155. The second electrode 140 may be formed on the phase-change material layer 130, i.e., in and outside the contact hole 155. In the present embodiment, the phase-change material layer 130 may be formed by using a damascene technique.

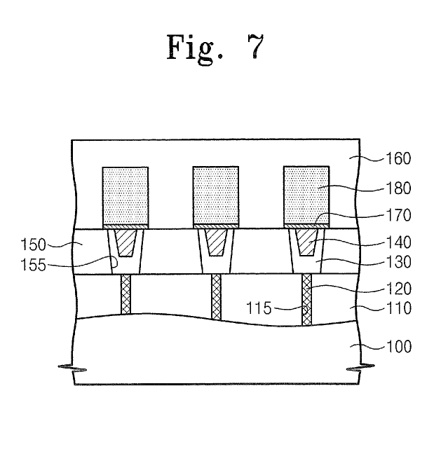

Referring to FIG. 7, unlike the embodiment illustrated in FIG. 5, the phase-change material layer 130 is provided on a sidewall and a bottom of the first insulating layer 150, and the second electrode 140 is provided on the phase-change material layer 130 and in the contact hole 155 of the first insulating layer 150. That is, the phase-change material layer 130 fills a part of the contact hole 155, and the second electrode 140 fills a remaining part of the contact hole 155. In the present embodiment, the phase-change material layer 130 may be formed by using a damascene technique.

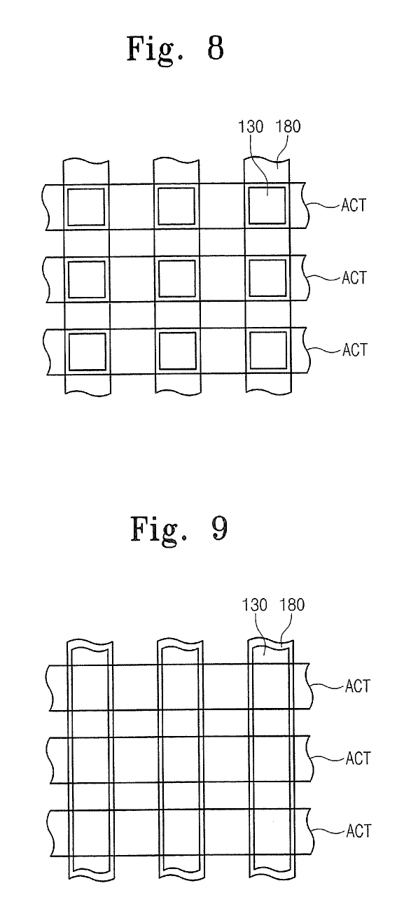

FIGS. 8 and 9 are plan views illustrating various configurations of the phase-change material layer 130 according to the embodiments of the present invention. Referring to FIG. 8, the phase-change material layer 130 may be an island pattern separated in an adjacent cell unit. Also, the phase-change material layer 130 may be formed such that at least two cells adjacent in a column or row direction share the phase-change material layer 130. For example, the phase-change material layer 130 illustrated in FIG. 9 may be a stripe pattern extending in a row or column direction.

A method of forming a phase-change memory device according to the embodiments of the present invention will now be described with reference to the accompanying drawings.

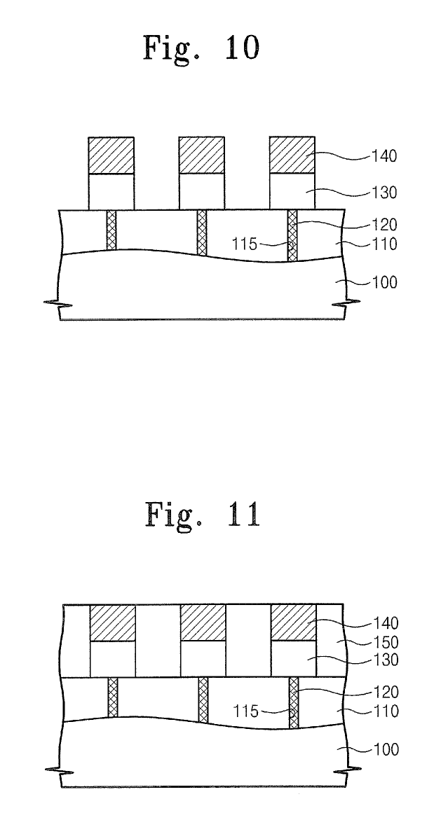

FIGS. 10 through 13 are sectional views for explaining a method of forming a phase-change memory device as illustrated in FIG. 3. Referring to FIG. 10, the substrate 100 on which a word line, a selection element and the like are formed is prepared. The word line may be formed by implanting impurity ions into an element region of the substrate 100 defined by a device isolation region. The selection element may be, for example, a diode. The selection element may be formed, for example, by forming an insulating layer having a selection element contact hole exposing the word line on the substrate on which the word line is formed, forming a semiconductor layer, such as a germanium layer, a silicon layer, or a silicon-germanium layer in the selection element contact hole, and implanting impurities into the semiconductor layer. The semiconductor layer in the selection element contact hole may be formed by using a selective epitaxial growth (SEG) or a solid phase epitaxial technique. The SEG technique is a method of growing a semiconductor epitaxial layer by using the word line exposed by the selection element contact hole as a seed layer. Unlike this, the solid phase epitaxial technique is a method which forms an amorphous semiconductor layer or a polycrystalline semiconductor layer in the selection element contact hole and then crystallizing the same.

After the word line, the selection element and the like are formed, the interlayer insulating layer 110 is formed on the substrate 100. The interlayer insulating layer 110 is patterned to form the electrode contact hole 115 defining a first electrode and exposing a corresponding selection element. A conductive material is filled in the electrode contact hole 115 to form the first electrode 120.

The phase-change material layer 130 correspondingly connected with the first electrode, and the second electrode 140 is formed. According to the present embodiment, the phase-change material layer 130 and the second electrode 140 may be formed by forming a phase-change material layer such as a chalcogenide, and a conductive material for the second electrode on the first electrode 120 and the interlayer insulating layer 110, and then patterning the phase-change material layer and the conductive material for the second electrode. Here, a capping layer may be further formed on the conductive material for the second electrode. Accordingly, a capping layer will be provided on the second electrode 140. This capping layer may be formed after the phase-change material layer and the conductive layer for the second electrode are patterned. In this case, the capping layer will be provided on side surfaces of the phase-change material layer 130 and the second electrode 140 as well as on an upper surface of the second electrode 140. This capping layer may be formed on the conductive material for the second electrode in embodiments to be described later.

Referring to FIG. 11, the first insulating layer 150 covering side surfaces of the phase-change material layer 130 and side surfaces of the second electrode 140 is formed. For example, an insulating material is deposited on the interlayer insulating layer 110 to cover the phase-change material layer 130 and the second electrode 140, and the deposited insulating material is etched and planarized until the second electrode 140 is exposed. For the planarizing etch, a chemical mechanical polishing, an etch back, or a combination thereof may be used. In the case where a capping layer is formed, the capping layer may act as an etch stop layer during the aforementioned planarizing etch process.

To prevent the phase-change material layer 130 from being distorted, the first insulating layer 150 is formed to have the same stress property as that of the phase-change material layer 130. For example, in the case where the phase-change material layer 130 has a tensile stress, the first insulating layer 150 is formed to have a tensile stress. For example, the first insulating layer 150 may have a tensile stress of about 5×10⁹ dyne/cm². The first insulating layer 150 is formed of a material with a high hardness such that the first insulating layer 150 may rigidly support the phase-change material layer 130. Alternatively, the first insulating layer is formed of a material having a tensile stress and a high hardness.

The first insulating layer may be formed of an oxide layer formed by a vapor deposition method using a high density plasma, a silicon oxide nitride (SiON) formed by a vapor deposition method, an oxide layer formed by a vapor deposition method using a reinforced plasma, and/or a silicon nitride layer formed by a vapor deposition method at a high temperature.

The first insulating layer 150 may be also formed of a material with a low heat conductivity in order to minimize a thermal interference between the first insulating layer 150 and the phase-change material layer 130 adjacent thereto.

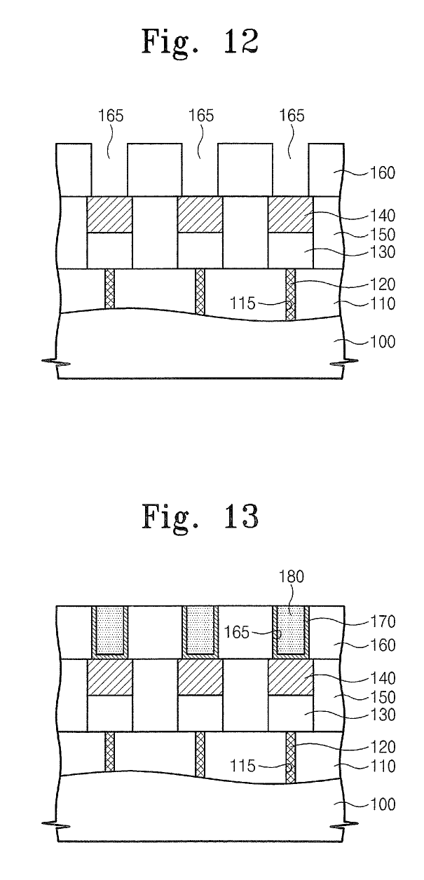

Next, a process of forming a bit line using a damascene technique will be described with reference to FIGS. 12 and 13. Referring to FIG. 12, the second insulating layer 160 having the stripe-shaped openings 165, which exposes the plurality of second electrodes 140 arranged in the column direction (or a direction vertical to the ground) and in which a bit line is formed, is formed on the first insulating layer 150. The stripe-shaped openings 165 may be formed, for example, by forming an insulating material layer covering the second electrode 140 and the first insulating layer 150, and then removing a part of the formed insulating material layer. The second insulating layer 160 is formed to have a different property than the first insulating layer 150. For example, to minimize the parasitic capacitance between adjacent bit lines, the second insulating layer 160 may be formed of a material with a low dielectric constant and/or a porous material. The second insulating layer 160 may be formed of a material with a low hardness in order to make it easy to form the stripe-shaped openings in which the bit line is formed. Also, unlike the first insulating layer 150, the second insulating layer 160 may be formed of a material with a high heat conductivity.

For example, the second insulating layer 160 may be formed of a material having a higher porosity degree, a lower hardness, a lower tensile stress, a higher heat conductivity and/or a lower dielectric constant than the first insulating layer 150. Alternatively, the second insulating layer 160 may be formed of a material not having a tensile stress.

For a low dielectric constant, the second insulating layer 160 may be formed of, for example, boron-doped silicon oxide (BSG), phosphorous-doped oxide (PSG), boron and phosphorous-doped oxide (BPSG), carbon-doped silicon oxide, hydrogen silsesquioxane (HSQ), methylsilsesquioxane (MSQ), SiLK, polyimide, polynorbornene, polymer dielectric material or the like. Also, the second insulating layer 160 may be formed of an oxide layer using an atomic layer deposition method, PETEOS oxide, flowable oxide (FOX) or the like.

Referring to FIG. 13, a conductive material, for example, copper is filled in the stripe-shaped opening 165 to form the copper bit line 180. Prior to filling copper, the conductive barrier layer 170 may be further formed in the opening 165. For example, after copper is formed in the opening 165 and on the second insulating layer 160, a planarizing etch process, such as a chemical mechanical polishing, an etch back is performed until the second insulating layer 160 is exposed.

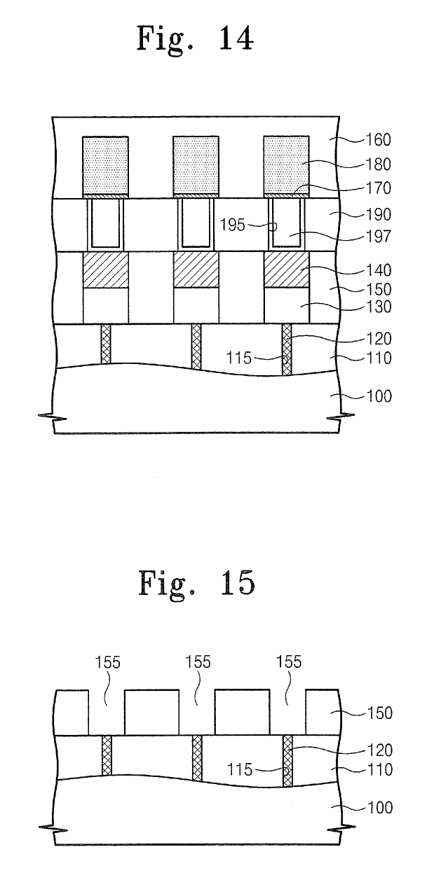

In the embodiment described with reference to FIGS. 10 through 13, the bit line may be formed by a conductive material patterning process which forms a desired conductive pattern by etching a conductive material layer, instead of a damascene technique. FIG. 14 illustrates a phase-change memory device formed by the aforementioned conductive material patterning process. Referring to FIG. 14, the interlayer insulating layer 190 is provided on the second electrode 140. The interlayer insulating layer 190 has the contact hole 195 exposing the corresponding second electrode 140. A conductive material is filled in the contact hole 195 to form the contact plug 197. The bit line 180 is provided such that it is electrically connected with the contact plugs 197 arranged in the same column. The second insulating layer 160 encloses the bit line 180. The conductive barrier layer 170 may be provided between the bit line 180 and the contact plug 197.

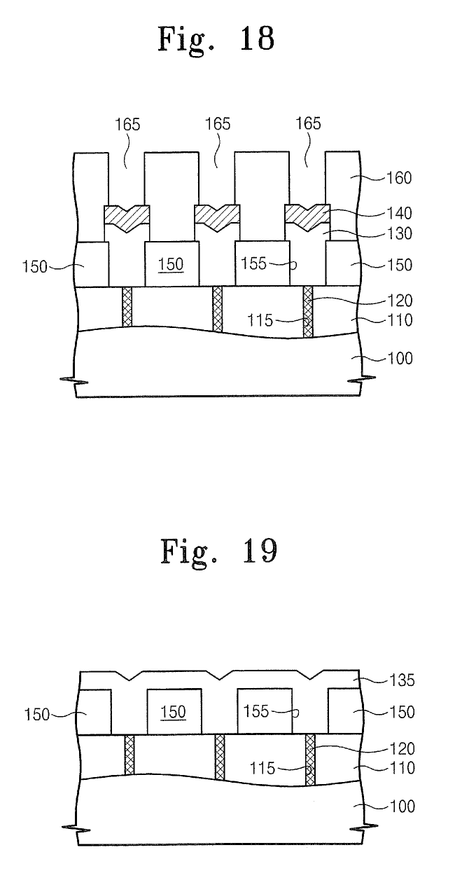

FIGS. 15 through 18 are partial sectional views for explaining a method of forming the phase-change memory device of FIG. 4. Unlike the embodiment described with reference to FIGS. 10 through 13, the phase-change material layer may be formed by using a damascene technique. The description overlapped with the method described in the previous embodiment will be omitted.

Referring to FIG. 15, the interlayer insulating layer 110 and the first electrode 120 are formed on the substrate 100. The first insulating layer 150 having the contact hole 155 defining a region where a phase-change material layer and a second electrode will be formed is formed. The contact hole 155 exposes the corresponding first electrode 120. As aforementioned, the first insulating layer 150 may be formed by depositing a material having a low heat conductivity, a high hardness, and/or a tensile stress, and removing a part of the deposited material such that the first electrode 120 is exposed.

Referring to FIG. 16, the chalcogenide layer 135 is formed in the contact hole 155 and on the first insulating layer 150. The conductive material layer 145 for a second electrode is formed on the chalcogenide layer 135.

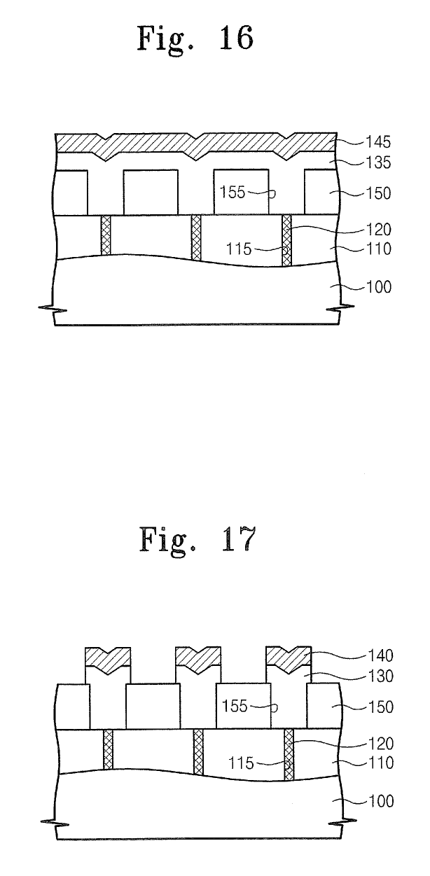

Referring to FIG. 17, the conductive material layer 145 for a second electrode and the chalcogenide layer 135 are patterned to form the phase-change material layer 130 and the second electrodes 140.

Referring to FIG. 1 8, a second insulating layer 160 having the stripe-shaped opening 165 exposing the plurality of second electrode 140, for example, arranged in a column direction. Thereafter, a conductive material such as copper is filled in the stripe-shaped opening 165 to form the bit line 180 as illustrated in FIG. 4.

In the present embodiment, the contact hole 155 of the first insulating layer 150 may be formed in a different pattern, for example, in a stripe pattern extending in the column direction. Thus, at least two adjacent phase-change memory cells share the phase-change material with each other.

According to the present embodiment, a part of the phase-change material adjacent to the first electrode 120, the phase-change material formed on a bottom of the contact hole 155 is not subject to an etch process. According to an embodiment of the present invention, since a phase-change of the phase-change material layer 130 takes place at a portion adjacent to the first electrode 120, it is possible to form a more reliable phase-change material layer.

With reference to FIGS. 19 through 22, a method of forming the phase-change memory device as illustrated in FIG. 5 will be described. Unlike the embodiment described with reference to FIGS. 15 through 18, a bit line directly contacts a phase-change material layer. Also, a phase-change material layer is defined within a contact hole of a first insulating layer. Referring to FIG. 19, as described above, the first insulating layer 150 having the contact hole 155 defining regions where the interlayer insulating layer 110, the first electrode 110 and a phase-change material layer will be formed is formed on the substrate 100. Next, the chalcogenide layer 135 for a phase-change material layer is formed in the contact hole 155 and on the first insulating layer 150.

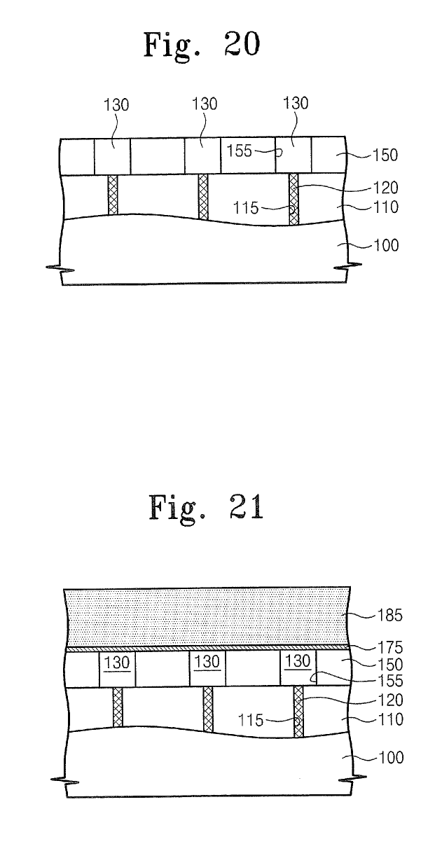

Referring to FIG. 20, a planarizing etch of the chalcogenide layer 135 is performed to remove the chalcogenide layer outside the contact hole 155 and thus form the phase-change material layer 130 defined in the contact hole 155.

Referring to FIG. 21, the conductive material layer 185 for a bit line is formed on the phase-change material layer 130 and the first insulating layer 150. Before the conductive material layer 185 for a bit line is formed, the conductive material layer 175 for a barrier layer may be further formed.

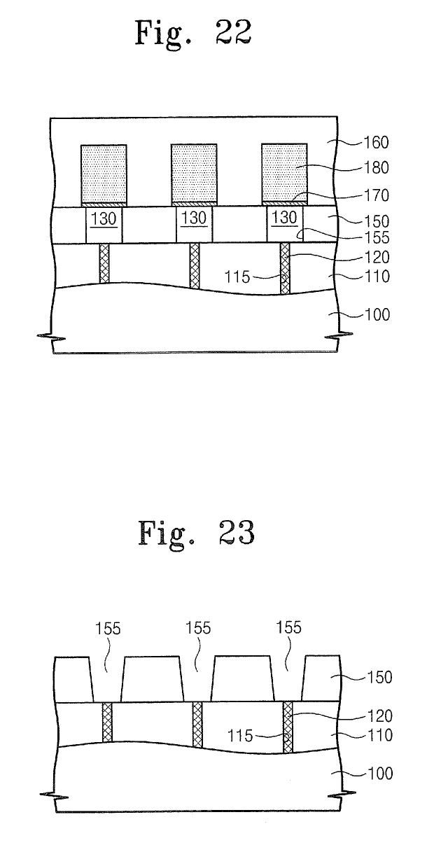

Referring to FIG. 22, the conductive material layer 185 for a bit line is patterned to form the bit line 180 connected with the phase-change layer 130. Thereafter, the second insulating layer 160 is formed on the first insulating layer 150 and the bit line 180 to cover the bit line 180.

In the present embodiment, an etch for the phase-change material layer in which a phase-change takes place is not basically generated.

In the present embodiment, the contact hole 155 of the first insulating layer 150 may be formed in a different pattern, for example, in a stripe pattern extending in the column direction. Thus, at least two adjacent phase-change memory cells share the phase-change material with each other.

FIGS. 23 through 26 are partial sectional views for explaining a method of forming the phase-change memory device of FIG. 6. Like in the embodiment described with reference to FIGS. 15 through 18, a phase-change material layer in the present embodiment is formed by using a damascene technique, but the phase-change material layer is formed at a constant thickness along a bottom and sidewalls of a contact hole of a first insulating layer. Referring to FIG. 23, the interlayer insulating layer 110, the first electrode 120 and the first insulating layer 150 having the contact hole 155 exposing the first electrode 120 are formed on the substrate 100. In the present embodiment, it will be understood that the width of the contact hole 155 of the first insulating layer 150 decreases as it travels toward the substrate 100 such that a phase-change material may fill a part of the contact hole 155 later, i.e., the phase-change material is formed along a sidewall and bottom of the contact hole 155.

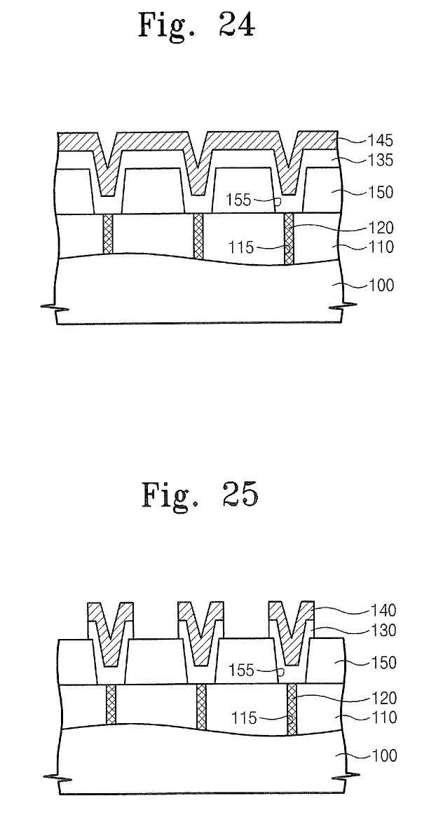

Referring to FIG. 24, the chalcogenide layer 135 for a phase-change material layer is formed along a bottom and sidewall of the contact hole 155. The conductive material layer 145 for a second electrode is formed on the chalcogenide layer 135 to fill the contact hole 155.

Referring to FIG. 25, a patterning process for the conductive material 145 for a second electrode and the chalcogenide layer 135 is performed to form the phase-change material layer 130 and second electrodes 140.

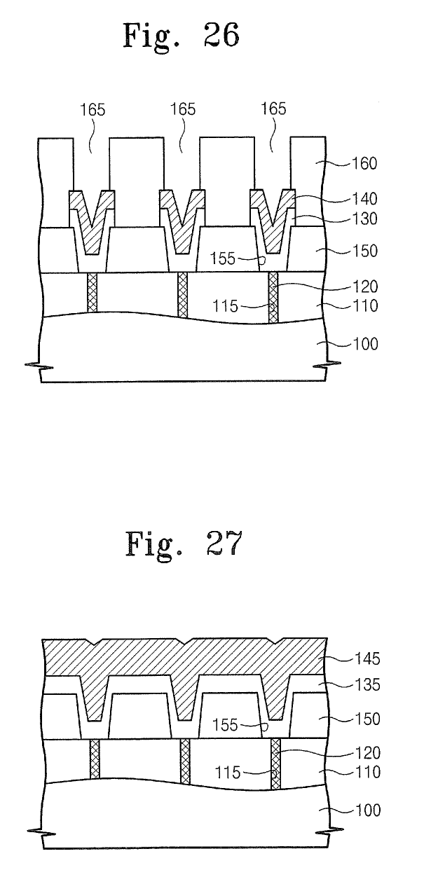

Referring to FIG. 26, the second insulating layer 160 having the stripe-shaped opening 165 exposing the second electrodes 140, for example, arranged in a column direction is formed. Thereafter, a conductive material such as copper is filled in the stripe-shaped opening 165 to form the bit line 180 as illustrated in FIG. 6.

In the present embodiment, an etch for the phase-change material layer in which a phase-change takes place is not basically generated.

In the present embodiment, the contact hole 155 of the first insulating layer 150 may be formed in a different pattern, for example, in a stripe pattern extending in the column direction. Thus, at least two adjacent phase-change memory cells share the phase-change material with each other.

With reference to FIGS. 27 through 29, a method of forming the phase-change memory device as illustrated in FIG. 7 will be described. Referring to FIG. 27, the interlayer insulating layer 110, the first electrode 120 and the first insulating layer 150 having the contact hole 155 exposing the first electrode 120 are formed on the substrate 100. In the present embodiment, it will be understood that the width of the contact hole 155 of the first insulating layer 150 decreases as it travels toward the substrate 100 such that a phase-change material is formed along a sidewall and bottom of the contact hole 155. The chalcogenide layer 135 for a phase-change material layer is formed along a bottom and sidewall of the contact hole 155. The conductive material layer 145 for a second electrode is formed on the chalcogenide layer 135 to completely fill the contact hole 155.

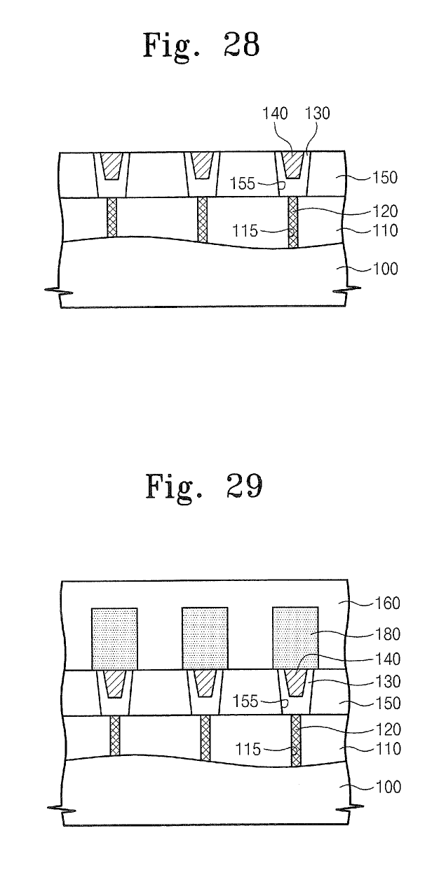

Referring to FIG. 28, the conductive material layer 145 outside the contact hole 155, and the chalcogenide layer 135 are removed to form the phase-change material layer 130 and the second electrodes 140 defined in the contact hole 155.

Referring to FIG. 29, a conductive material layer for a bit line is deposited on the second electrode 140 and the first insulating layer 150, and is then patterned to form the bit line 180 connected with the second electrode 140. Thereafter, the second insulating layer 160 is formed on the first insulating layer 150 and the bit line 180 to cover the bit line 180.

In the present embodiment, an etch for the phase-change material layer in which a phase-change takes place is not basically generated.

In the present embodiment, the contact hole 155 of the first insulating layer 150 may be formed in a different pattern, for example, in a stripe pattern extending in the column direction. Thus, at least two adjacent phase-change memory cells share the phase-change material with each other.

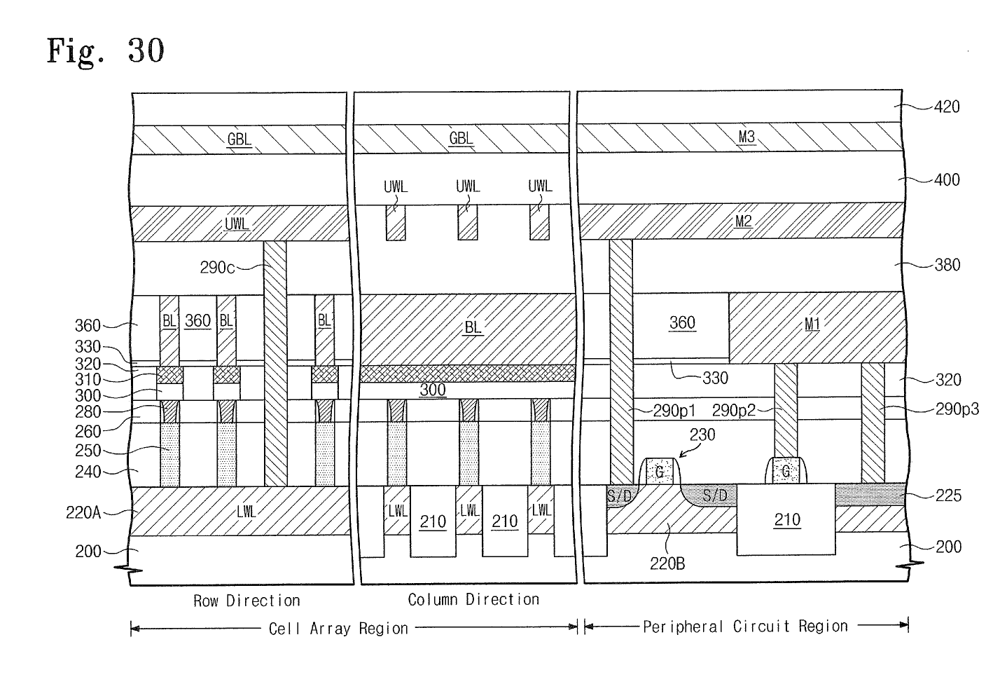

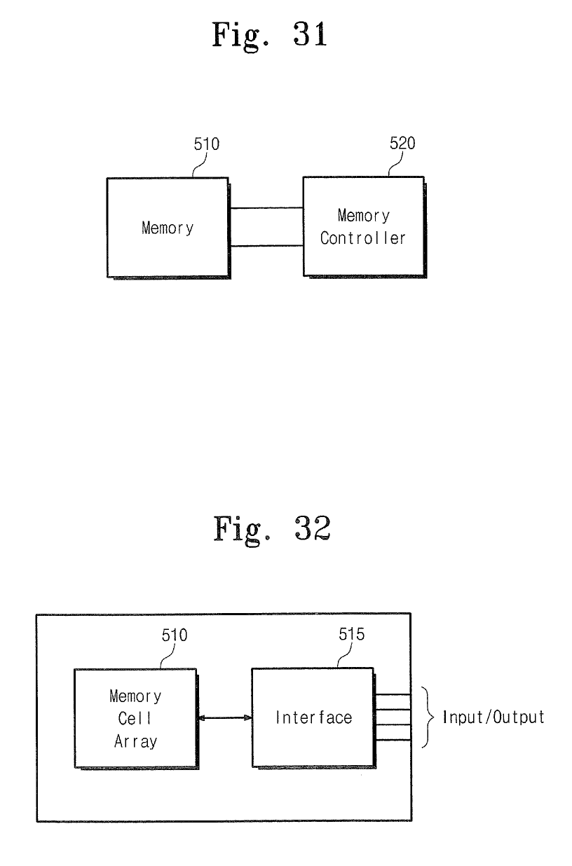

FIG. 30 is sectional views illustrating a phase-change memory device according to an embodiment of the present invention, and shows sections of a memory cell array region and a peripheral circuit region. For more apparent understanding of a phase-change memory device according to an embodiment of the present invention, a section of the memory cell array region in the row direction (taken in an extending direction of the word line) and a section of the memory cell array region in the column direction (taken in an extending direction of the bit line) are all shown. The left drawing of FIG. 30 is a section view in the row direction, the middle drawing is a sectional view in the column direction, and the right drawing of FIG. 30 is a sectional view in the peripheral circuit region.

Referring to FIG. 30, a plurality of word lines, i.e., the lower word lines LWL are provided on the semiconductor substrate 200 of the memory cell array region. The lower word lines LWL may be formed, for example, by doping a semiconductor layer with n-type impurities. For example, the lower word lines LWL may extend in the row direction. The lower word lines LWL may include a metal layer, a conductive metal nitride layer, a conductive metal oxide layer, a conductive oxide nitride layer, a silicide layer, a metal alloy layer or combinations thereof. An insulating layer, such as a device isolation layer 210, may electrically insulate the lower word lines LWL adjacent to each other. In the peripheral circuit region, a driver element for driving a memory cell array region, for example, the driver transistor 230 may be provided on the active region 220B defined by the device isolation layer 210.

A plurality of the bit lines BL is provided on the substrate 200 of the memory cell array region to cross the lower word lines LWL. In the peripheral circuit region, the first conductive line M1 corresponding to the bit line BL is provided. The first conductive line M1 may be electrically connected with the gate G, the source/drain region S/D of the driver transistor 230. The bit line BL and the first conductive line may include copper. According to an embodiment of the present invention, since the bit line BL and the first conductive line M1 may be formed of copper using a damascene technique, it is possible to decrease the resistances of the bit line BL and the first conductive line M1.

The phase-change material layer 300 is positioned between the lower word line LWL and the bit line BL. The first electrode 280 and the selection element 250 are provided between the phase-change material layer 300 and the lower word line LWL, and the second electrode 310 is provided between the phase-change material layer 300 and the bit line BL. In other words, the first electrode 280 and the second electrode 310 are electrically connected with the phase-change material layer 300. The first electrode 280 may be used, for example, as a heater for heating the phase-change material layer 300. The first electrode 280 is electrically connected with the lower word line LWL, for example, through the selection element 250 such as a diode. The second electrode 310 is electrically connected with the bit line BL.

The diode 250 functioning as a selection element may include an n-type semiconductor layer and a p-type semiconductor layer stacked on the substrate 200. The p-type semiconductor layer may be adjacent to the first electrode 280 and the n-type semiconductor layer may be adjacent to the lower word line LWL.

In the cell array region, the cell contact plug 290c, which is adjacent to the bit line BL and is electrically connected with the lower word line LWL, may be provided. The cell contact plug 290c may be made in a multi-layer structure. For example, the cell contact plug 290c may include a titanium nitride layer, a tungsten layer and a copper layer sequentially stacked in a sequence close to the substrate 200. The cell contact plug 290c may be provided, for example, in a cell contact hole penetrating the third insulating layer 380, the second insulating layer 360, the first insulating layer 320, the second interlayer insulating layer 260 and the first interlayer insulating layer 240.

Meanwhile, in the peripheral circuit region, the peripheral contact plugs 290p1-290p3 corresponding to the cell contact plug 209c may be provided. The peripheral contact structures 290p1-290p3 are electrically connected with the gate G, the source/drain region S/D of the driver transistor 230, or the impurity diffusion region 225. Similarly with the cell contact plug, the peripheral contact plug 290p1 connected with the source/drain region S/D may include a titanium nitride layer, a tungsten layer and a copper layer sequentially stacked in a sequence close to the substrate 200. The peripheral contact plugs 290p2 and 290p3 connected with the gate G may include, for example, a titanium nitride layer and a tungsten layer stacked in a sequence close to the substrate 200.

Similarly with the cell contact plug 290c1, the peripheral contact plug 290p1 may be provided in a peripheral contact hole penetrating the third interlayer insulating layer 380, the second insulating layer 360, the first insulating layer 320, the second interlayer insulating layer 260, and the first interlayer insulating layer 240. The peripheral contact plugs 290p2 and 290p3 may be provided in a peripheral contact hole penetrating the first insulating layer 320, the second interlayer insulating layer 260 and the first interlayer insulating layer 240.

According to embodiments of the present invention, the etch stop layer 330 may be provided between the second insulating layer 360 and the first insulating layer 320. This etch stop layer 330 is formed of a material having an etch selectivity with respect to the second insulating layer 360.

The upper word line UWL for decreasing the resistance of the lower word line LWL may be, for example, connected with the cell contact plug 290c2. In the meanwhile, in the peripheral circuit region, the second conductive line M2 corresponding to the upper word line UWL may be provided. The second conductive line M2 may be, for example, connected with the peripheral contact plug 290p1. Alternatively, the second conductive line M2 may be connected with the first conductive line M1. According to an embodiment of the present invention, since the upper word line UWL and the second conductive line M2 may be formed of copper using a damascene technique, the resistances of the upper word line UWL and the second conductive line M2 can be decreased.

In the cell array region, the global bit line GBL is provided on the upper word line UWL, and in the peripheral circuit region, the third conductive line M3 corresponding to the global bit line GBL is provided on the second conductive line M2. The global bit line GBL and the third conductive line M3 may include copper. Since the global bit line GBL and the third conductive line M3 may be formed of copper using a damascene technique, the resistances of the global bit line GBL and the third conductive line M3 can be decreased. The third conductive line M3 may be electrically connected with the second conductive line M2. The fourth interlayer insulating layer 400 may be provided between the global bit line GBL and the upper word line UWL.

The passivation layer 420 may be provided on the global bit line GBL and the third conductive line M3.

The first insulating layer 320 encloses side surfaces of the phase-change material layer 300, and the second insulating layer 360 encloses side surfaces of the bit line BL and the first conductive line M1.

The interlayer insulating layer 380 is provided between the bit line BL and the upper word line UWL and between the first conductive line M1 and the second conductive line M2. The interlayer insulating layer 400 is provided between the upper word line UWL and the global bit line GBL, and between the second conductive line M2 and the third conductive line M3.

According to another embodiment of the present invention, in order to obtain a higher integration density, the phase-change memory device may be formed in a multi-level on a substrate.

The aforementioned resistive memory device may be embodied in various forms or may be used as one element for various apparatuses. For example, the aforementioned resistive memory device may be applied for realizing various types of memory cards, USB memories, solid-state drivers, etc.

FIG. 31 illustrates an apparatus including a resistive memory device according to an embodiment of the present invention. As shown in the drawing, the apparatus of the present embodiment includes the memory 510 and the memory controller 520. The memory 510 may include a resistive memory device according to the above-described embodiments of the present invention. The memory controller 520 may supply an input signal for controlling an operation of the memory 510. For example, the memory controller 520 may supply a command language and an address signal. The memory controller 520 may control the memory 510 based on a received control signal.

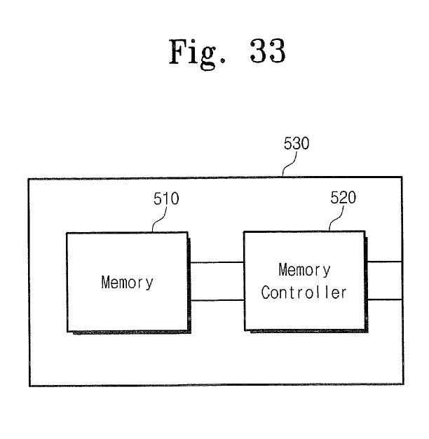

FIG. 32 illustrates an apparatus including a resistive memory device according to an embodiment of the present invention. As shown in the drawing, the apparatus of the present embodiment includes the memory 51 0 connected with the interface 515. The memory 510 may include a memory device according to the aforementioned embodiments of the present invention. The interface 515 may provide, for example, an external input signal. For example, the interface 515 may provide a command language and an address signal. The interface 515 may control the memory 510 based on a control signal that is generated from an outside and received.

FIG. 33 illustrates an apparatus including a resistive memory device according to an embodiment of the present invention. As shown in the drawing, the apparatus of the present invention is similar to the apparatus of FIG. 31 except that the memory 510 and the memory controller 520 are embodied by a memory card 530. For example, the memory card 530 may be a memory card satisfying a standard for compatibility with electronic appliances, such as digital cameras, personal computers or the like. The memory controller 520 may control the memory 510 based on a control signal that the memory card receives from a different device, for example, an external device.

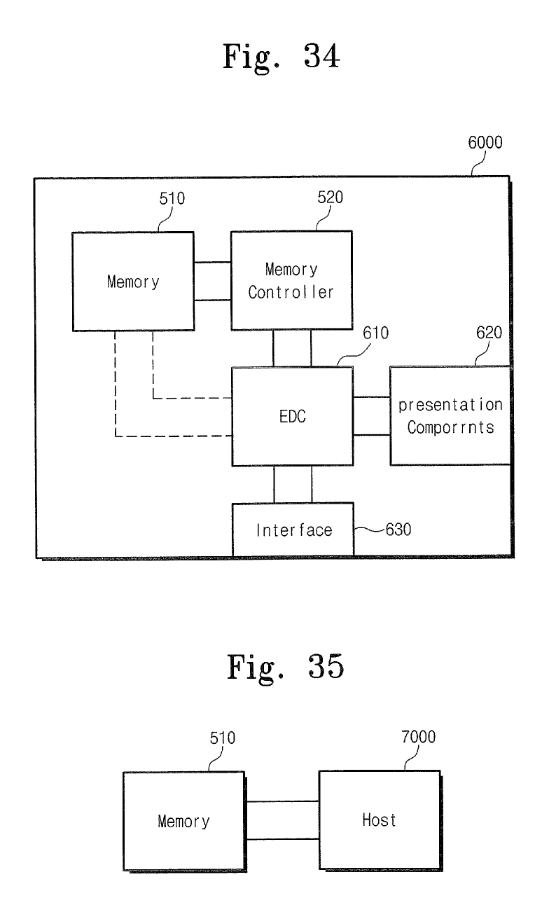

FIG. 34 illustrates the mobile device 6000 including a resistive memory device according to an embodiment of the present invention. The mobile device 6000 may be an MP3, a video player, a video, audio player or the like. As shown in the drawing, the mobile device 6000 includes the memory 510 and the memory controller 520. The memory 510 includes a resistive memory device according to the aforementioned embodiments of the present invention. The mobile device 6000 may include the encoder and decoder EDC 610, the presentation component 620, and the interface 630. Data such as videos and audios may be exchanged between the memory 510 and the encoder and decoder EDC 610 via the memory controller 520. As indicated by a dotted line, data may be directly exchanged between the memory 510 and the encoder and decoder EDC 610.

EDC 610 may encoder data to be stored in the memory 510. For example, EDC 610 may encode an audio data into an MP3 file and store the encoded MP3 file in the memory 510. Alternatively, EDC 610 may encode an MPEG video data (e.g., MPEG3, MPEG4, etc.) and store the encoded video data in the memory 510. Also, EDC 610 may include a plurality of encoders that encode a different type of data according to a different data format. For example, EDC 610 may include an MP3 encoder for audio data and an MPEG encoder for video data. EDC 610 may decode output data from the memory 510. For example, EDC 610 may decode audio data outputted from the memory 510 into an MP3 file. Alternatively, EDC 610 may decode video data outputted from the memory 510 into an MPEG file. Also, EDC 610 may include a plurality of decoders that decode a different type of data according to a different data format. For example, EDC 610 may include an MP3 decoder for audio data and an MPEG decoder for video data. Also, EDC 610 may include only a decoder. For example, previously encoded data may be delivered to EDC 610, decoded and then delivered to the memory controller 520 and/or the memory 510.

EDC 610 receives data for encoding or previously encoded data via the interface 630. The interface 630 may comply with a well-known standard (e.g., USB, firewire, etc.). The interface 630 may include one or more interfaces. For example, the interface 630 may include a firewire interface, a USB interface, etc. The data provided from the memory 510 may be outputted via the interface 630.

The representation component 620 represents data decoded by the memory 510 and/or EDC 610 such that a user can perceive the decoded data. For example, the representation component 620 may include a display screen displaying a video data, etc., and a speaker jack for outputting an audio data.

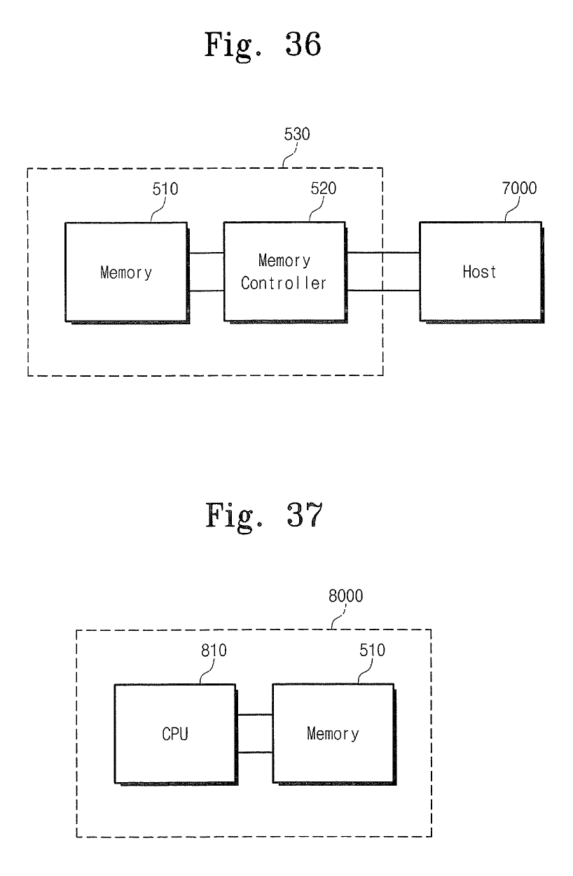

FIG. 35 illustrates an apparatus including a resistive memory device according to an embodiment of the present invention. As shown in the drawing, the memory 510 may be connected with the host system 7000. The memory 510 includes a resistive memory device according to the aforementioned embodiments of the present invention. The host system 7000 may be a processing system such as a personal computer, a digital camera, etc. The memory 510 may be a detachable storage medium form, for example, a memory card, a USB memory, or a solid-state driver SSD. The host system 7000 may provide an input signal for controlling an operation of the memory 510. For example, the host system 7000 may provide a command language and an address signal.

FIG. 36 illustrates an apparatus including a resistive memory device according to an embodiment of the present invention. In this embodiment, the host system 7000 is connected with the memory card 530. The host system 7000 supplies a control signal to the memory card 530 such that the memory controller 520 controls an operation of the memory 510.

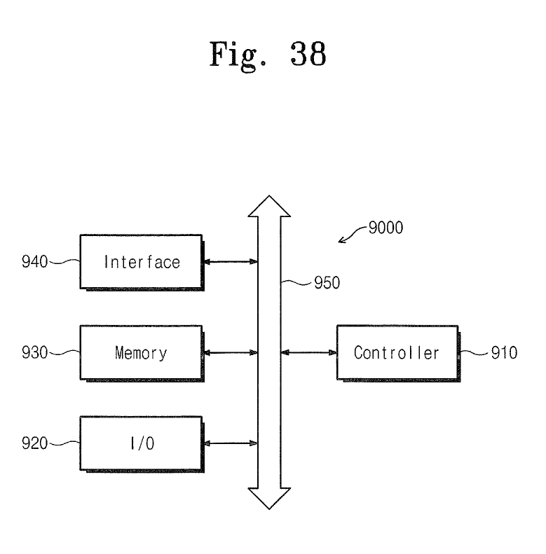

FIG. 37 illustrates an apparatus including a resistive memory device according to an embodiment of the present invention. As shown in the drawing, according to the apparatus of the present embodiment, the memory 510 may be connected with the central processing unit CPU 810 in the computer system 8000. For example, the computer system 8000 may be a personal computer, a personal data assistant, etc. The memory 510 may be connected with the CPU 810 via a bus.

FIG. 38 illustrates an apparatus including a resistive memory device according to an embodiment of the present invention. As shown in the drawing, the apparatus 9000 according to the present embodiment may include the controller 910, the input/output unit 920 such as a keyboard, a display or the like, the memory 930, and the interlace 940. In the present embodiment, the respective components constituting the apparatus may be connected with each other via a bus 950.

The controller 910 may include at least one microprocessor, digital processor, microcontroller, or processor. The memory 930 may store a command executed by data and/or the controller 910. The interface 940 may be used to transmit data from a different system, for example, a communication network, or to a communication network. The apparatus 9000 may be a mobile system such as a PDA, a portable computer, a web tablet, a wireless phone, a mobile phone, a digital music player, a memory card or a different system that can transmit and/or receive information.

According to embodiments of the present invention, it is possible to form a reliable phase-change memory device with a high integration density.

According to embodiments of the present invention, an interface characteristic between a phase-change material and an electrode can be enhanced to decrease the set resistance.

According to embodiments of the present invention, it is possible to form a resistive memory device and a phase-change memory device that can operate at a high speed.

According to embodiments of the present invention, heat transfer between adjacent memory cells can be minimized.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

1. A resistive memory device comprising:
a resistive memory element on a substrate;
a first insulating layer covering a side surface of the resistive memory element;
a conductive line on the resistive memory element; and
a second insulating layer covering a side surface of the conductive line,
wherein the first insulating layer and the second insulating layer have a difference in at least one selected from the group consisting of hardness, stress, dielectric constant, heat conductivity and porosity degree.

2. The resistive memory device of claim 1, wherein the first insulating layer has a higher hardness than the second insulating layer.

3. The resistive memory device of claim 2, wherein the first insulating layer has a lower porosity degree than the second insulating layer.

4. The resistive memory device of claim 1, wherein the second insulating layer has a lower dielectric constant than the first insulating layer.

5. The resistive memory device of claim 4, wherein the second insulating layer comprises a boron-doped silicon oxide layer, a phosphorous-doped oxide layer, a boron and phosphorous-doped oxide layer, a carbon-doped silicon oxide layer, a hydrogen silsesquioxane (HSQ) layer, a methylsilsesquioxane (MSQ) layer, a SiLK layer, a polyimide layer, a polynorbornene layer, or a polymer dielectric material layer.

6. The resistive memory device of claim 4, wherein the second insulating layer comprises a low-k material layer that has a lower dielectric constant than silicon oxide (SiO₂).

7. The resistive memory device of claim 1, wherein the second insulating layer has a higher porosity degree than the first insulating layer.

8. The resistive memory device of claim 7, wherein the second insulating layer has a lower dielectric constant than the first insulating layer.

9. The resistive memory device of claim 1, wherein the resistive memory element comprises a phase-change memory element, and the first insulating layer has a tensile stress and a higher hardness and a lower porosity degree than the second insulating layer.

10. The resistive memory device of claim 1, wherein the conductive line comprises a bit line electrically connected with the resistive memory element.

11.-19. (canceled)
